(19) United States
(12) Patent Application Publication
(10) Pub. No.: US 2025/0393125 A1
(43) Pub. Date: Dec. 25, 2025

(54) FLEXIBLE PRINTED CIRCUIT BOARD, DISPLAY DEVICE COMPRISING THE SAME, METHOD FOR MANUFACTURING THE SAME, AND ELECTRONIC DEVICE COMPRISING THE SAME

(71) Applicant: Samsung Display Co., Ltd., Yongin-si (KR)

(72) Inventors: Jae-Hwan JEON, Yongin-si (KR); Taekyoung KIM, Yongin-si (KR); Hun-Tae KIM, Yongin-si (KR); Kyoung Ho PARK, Yongin-si (KR); Jian SHIN, Yongin-si (KR); Taehee YOON, Yongin-si (KR)

(21) Appl. No.: 19/096,701

(22) Filed: Mar. 31, 2025

(30) Foreign Application Priority Data
Jun. 25, 2024 (KR) 10-2024-0083191
Jul. 9, 2024 (KR) 10-2024-0090260

(51) Int. Cl. H05K 1/11; H05K 1/03; H05K 3/40; H05K 5/00

(52) U.S. Cl. CPC H05K 1/118; H05K 1/0386; H05K 1/111; H05K 3/4015; H05K 5/0069; H05K 2201/032; H05K 2201/0367; H05K 2201/10212; H05K 2201/10234; H05K 2203/0195; H05K 2203/1189

(57) ABSTRACT

A flexible printed circuit board includes a base film, a wiring layer disposed on the base film and a plurality of conductive balls partially embedded in the upper surface of the wiring layer. A display device includes a display panel including a display area and a peripheral area, a flexible printed circuit board facing and bonded to a pad portion disposed in the peripheral area and a nonconductive film disposed between the pad portion and the flexible printed circuit board, wherein the flexible printed circuit board includes a plurality of conductive balls partially embedded on an upper surface of a wiring layer disposed on a base film, and the pad portion has a portion that comes into contact with the plurality of conductive balls.

This application claims priority to Korean Patent Application No. 10-2024-0090260, filed on Jul. 9, 2024, and Korean Patent Application No. 10-2024-0083191, filed on Jun. 25, 2024, and all the benefits accruing therefrom under 35 U.S.C. § 119, the contents of which in their entirety are herein incorporated by reference.

### BACKGROUND

### 1. Field

The invention relates to a flexible printed circuit board, and more particularly to a flexible printed circuit board, a display device including the same, and a manufacturing method of a flexible printed circuit board.

### 2. Description of the Related Art

A display device such as a liquid crystal display (LCD) or organic light emitting diode display (OLED) includes a display panel displaying an image, and a driver such as a gate driver and a data driver for driving the display panel. The data driver may be formed with a separate chip and may be electrically connected to the display panel. The gate driver may be integrated into the display panel without being formed as a chip. The display device may also include a touch panel and a touch driver for driving the display device.

The display panel includes a pad region in which pads for receiving signals from the outside are arranged, and an electrical part such as a flexible printed circuit board is bonded to the pad region. When the flexible printed circuit board is bonded, the pad region of the display panel and the pad of the flexible printed circuit board may be electrically connected. As the resolution of the display devices increases, the size and pitch of the pads become smaller, so the connection reliability of the flexible printed circuit boards should be ensured.

### SUMMARY

An embodiment includes a flexible printed circuit board capable of ensuring the reliability of the connection with the display device without a separate conductive adhesive member, a display device including the same, and a manufacturing method of the flexible printed circuit board.

A flexible printed circuit board, according to an embodiment, includes a base film, a wiring layer disposed on the base film and a plurality of conductive balls partially embedded in an upper surface of the wiring layer.

In an embodiment, the plurality of conductive balls may have a higher hardness than the wiring layer.

In an embodiment, the wiring layer may include copper (Cu), and the plurality of conductive balls may include at least one selected from a group consisting of nickel (Ni), molybdenum (Mo), chromium (Cr), tantalum (Ta), and titanium (Ti).

In an embodiment, the plurality of conductive balls may be in the form of balls coated with a conductive material on a polymer.

In an embodiment, the plurality of conductive balls may protrude from the upper surface of the wiring layer.

In an embodiment, the wiring layer may include a plurality of wires, wherein a width of each of the plurality of wires may be larger than a diameter of each of the plurality of conductive balls.

In an embodiment, a portion of an upper surface of the base film in contact with the wiring layer may have a higher step than a portion not in contact with the wiring layer.

In an embodiment, in a thickness measured in a direction perpendicular to the upper surface of the base film, a thickness of the step may be smaller than a thickness of the wiring layer.

In an embodiment, an integrated circuit chip disposed on the base film in a region distinct from the wiring layer may be further included, and the integrated circuit chip may be configured to be electrically connected to the wiring layer.

A display device, according to an embodiment, includes a display panel including a display area and a peripheral area, a flexible printed circuit board facing and bonded to a pad portion disposed in the peripheral area and a nonconductive film disposed between the pad portion and the flexible printed circuit board, wherein the flexible printed circuit board includes a plurality of conductive balls partially embedded on an upper surface of a wiring layer disposed on a base film, and the pad portion has a portion that comes into contact with the plurality of conductive balls.

In an embodiment, the wiring layer may include a plurality of wires, wherein no conductive ball may be disposed between the plurality of wires.

In an embodiment, the pad portion may include a plurality of pads, wherein no conductive ball may be disposed between the plurality of pads.

In an embodiment, the plurality of conductive balls may protrude from the upper surface of the wiring layer.

A manufacturing method of a flexible printed circuit board, according to an embodiment, includes partially embedding a plurality of conductive balls onto an upper surface of a wiring layer disposed on a base film, and removing the remaining conductive balls that are not embedded in the wiring layer.

In an embodiment, the plurality of conductive balls may have a higher hardness than the wiring layer.

In an embodiment, partially embedding the plurality of conductive balls onto the upper surface of the wiring layer may include positioning the plurality of conductive balls on the base film on which the wiring layer is formed, and pressing at least some of the plurality of conductive balls onto the upper surface of the wiring layer by using a roller.

In an embodiment, removing the remaining conductive balls may include etching the remaining conductive balls disposed on a portion of the upper surface of the base film that does not come into contact with the wiring layer.

In an embodiment, removing the remaining conductive balls may include removing the remaining conductive balls through a cleaning process.

In an embodiment, partially embedding the plurality of conductive balls onto the upper surface of the wiring layer may include forming a wire formation layer on the base film, embedding the plurality of conductive balls on the upper surface of the wire formation layer, and patterning the wire formation layer to form a wiring layer.

In an embodiment, forming the wiring layer may include patterning the wire formation layer in which the plurality of conductive balls are embedded to remove some of the plurality of conductive balls.

According to embodiments of the flexible printed circuit board and the display device including the same, a reliable connection with the display device may be secured without introducing a separate conductive adhesive member.

An electronic device, according to the embodiments, comprises a display device, a memory, a processor, and a power supply module, the display device comprising: a display panel including a display area and a peripheral area; a flexible printed circuit board facing and bonded to a pad portion disposed in the peripheral area; and a nonconductive film disposed between the pad portion and the flexible printed circuit board, wherein the flexible printed circuit board includes a plurality of conductive balls partially embedded into an upper surface of a wiring layer disposed on a base film, and the pad portion has a portion that comes into contact with the plurality of conductive balls.

In an embodiment, the wiring layer may include a plurality of wires, and no conductive ball is disposed between the plurality of wires.

### BRIEF DESCRIPTION OF THE DRAWINGS

FIG. 1 is a schematic layout view of a display device, according to an embodiment.

FIG. 2 is a schematic layout view of a display device, according to an embodiment.

FIG. 3 is a cross-sectional view taken along a line III-III′ of FIG. 1, according to an embodiment.

FIG. 4 is a cross-sectional view of a flexible printed circuit board shown in FIG. 3, according to an embodiment.

FIG. 5 is a cross-sectional view illustrating a flexible printed circuit board, according to another embodiment.

FIG. 6 is a cross-sectional view showing a manufacturing method of a flexible printed circuit board, according to an embodiment.

FIG. 7 is a cross-sectional view of a flexible printed circuit board showing a manufacturing method of a flexible printed circuit board, according to an embodiment.

FIG. 8 is a cross-sectional view of a flexible printed circuit board showing a manufacturing method of a flexible printed circuit board, according to an embodiment.

FIG. 9 is a cross-sectional view of a flexible printed circuit board showing a manufacturing method of a flexible printed circuit board, according to an embodiment.

FIG. 10 is a cross-sectional view of a flexible printed circuit board showing a manufacturing method of a flexible printed circuit board, according to an embodiment.

FIG. 11 is a cross-sectional view showing a manufacturing method of a flexible printed circuit board, according to another embodiment.

FIG. 12 is a cross-sectional view showing a manufacturing method of a flexible printed circuit board, according to another embodiment.

FIG. 13 is a cross-sectional view showing a manufacturing method of a flexible printed circuit board, according to another embodiment.

FIG. 14 is a cross-sectional view showing a manufacturing method of a flexible printed circuit board, according to another embodiment.

FIG. 15 is a cross-sectional view illustrating a process of bonding a flexible printed circuit board, a nonconductive film, and a pad portion of a display panel, according to an embodiment.

FIG. 16 is a cross-sectional view illustrating a process of bonding a flexible printed circuit board, a nonconductive film, and a pad portion of a display panel, according to an embodiment.

FIG. 17 is a cross-sectional view illustrating a portion of a display area in a display device, according to an embodiment.

FIG. 18 is a block diagram of an electronic device, according to an embodiment.

FIG. 19 shows schematic diagrams of electronic devices, according to various embodiments.

### DETAILED DESCRIPTION

Hereinafter, the invention will be described more fully with reference to the accompanying drawings, in which exemplary embodiments of the invention are shown. As those skilled in the art would realize, the described embodiments may be modified in various different ways, all without departing from the spirit or scope of the invention.

Parts irrelevant to the description will be omitted to clearly describe the present disclosure, and like elements will be designated by like reference numerals throughout the specification.

In addition, the size and thickness of each configuration shown in the drawings are arbitrarily shown for understanding and ease of description, but the invention is not limited thereto. In the drawings, the thicknesses of layers, films, panels, regions, etc., are exaggerated for clarity. In the drawings, for understanding and ease of description, the thickness of some layers and areas is exaggerated.

It should be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise,” and variations such as “comprises” and “comprising,” should be understood to imply the inclusion of stated elements but not the exclusion of any other elements.

Further, in the specification, the phrase “on a plane” means viewing the object portion from the top, and the phrase “on a cross-section” means viewing a cross-section of which the object portion is vertically cut from the side.

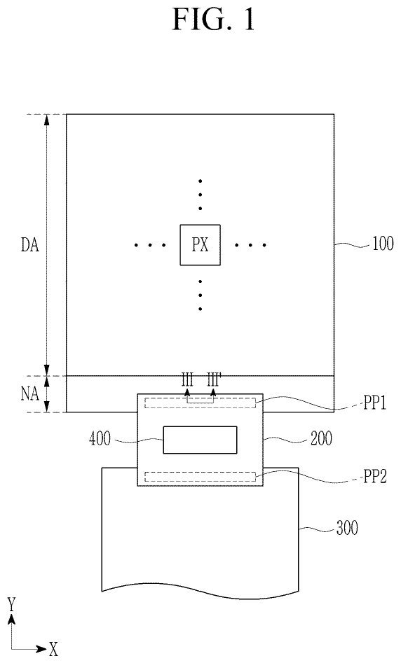

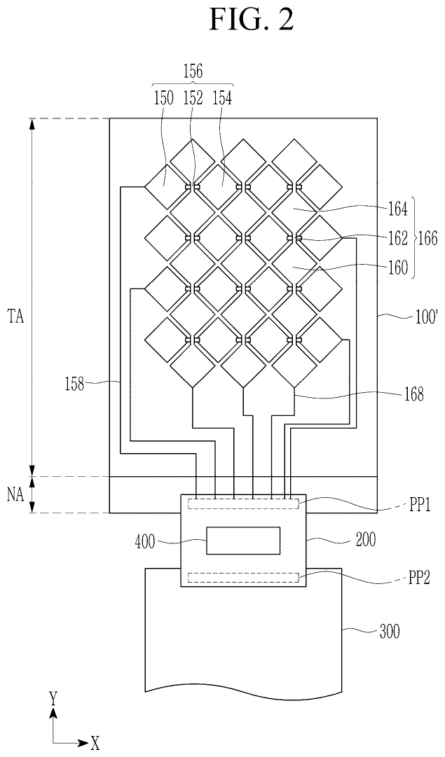

FIG. 1 and FIG. 2 are schematic layout views of a display device, according to an embodiment.

In an embodiment and referring to FIG. 1, a display device includes a display panel 100, a flexible printed circuit board 200 connected to the display panel 100, and a printed circuit board (PCB) 300 connected to the flexible printed circuit board 200. The display panel 100 may be an organic light emitting panel or a liquid crystal panel, but is not limited thereto.

In an embodiment, the display panel 100 includes a display area DA that displays an image and a peripheral area NA outside the display area DA. The display area DA is equipped with elements and wires for generating or transmitting various signals applied to the display area DA. In FIG. 1, although only one side edge region (e.g., a lower region) of the display panel 10 is shown as the non-display area NA, in another embodiment the other side edge regions (e.g., left and right edges and/or an upper edge) of the display panel 10 may be the non-display area NA. Although the display area DA is depicted as a quadrangle, the display area DA may have various shapes such as a circle, an ellipse, a polygon, etc. in addition to a quadrangle.

For example, in an embodiment, in the display area DA of the display panel 100, the pixels PX are arranged in a matrix. The display area DA also has signal lines such as gate lines (not shown) and data lines (not shown). The gate lines may extend in a first direction X. The data lines may extend in a second direction Y directed perpendicular to the first direction X. Here, each pixel PX may be connected to the gate line and the data line. Additionally, the display area DA may have driving voltage lines (not shown) extending from the gate lines and the data lines in, for example, the second direction Y, and transmitting the driving voltage to the pixels PX.

In an embodiment, a pad portion PP1, where electrodes for receiving signals from the outside of the display panel 100 are arranged, is disposed in the peripheral area NA of the display panel 100. One terminal of the flexible printed circuit board 200 may be connected to the pad portion PP1. The other terminal of the flexible printed circuit board 200 may be connected to the pad portion PP2 of the printed circuit board (PCB) 300, and the printed circuit board (PCB) 300 may transmit signals such as, for example, an image data.

In an embodiment, a driving apparatus that generates and/or processes various signals for driving the display panel 100 may be disposed in the peripheral area NA of the display panel 100 or on the flexible printed circuit board 200, or may be disposed on an external printed circuit board (PCB) 300. The driving apparatus may include a data driver that applies a data signal to the data line, a gate driver that applies a gate signal to the gate line, and a signal controller that controls the data driver and the gate driver.

According to an embodiment, the data driver may be mounted in a form of an integrated circuit chip 400 disposed on the flexible printed circuit board 200 and connected to the pad portion PP1. Unlike the one shown, the data driver may be mounted in the peripheral area NA between the display area DA and the pad portion PP1 in a form of an integrated circuit chip. The gate driver may be integrated in the peripheral area (not shown) on the left and/or right edges of the display panel 100 and may be provided in a form of an integrated circuit chip. The signal controller may be formed of an integrated circuit chip 400 like the data driver or may be provided as a separate integrated circuit chip.

In an embodiment and referring to FIG. 2, the display device may include a touch panel 100′. The touch panel 100′ may include a touch region TA and the peripheral area NA other than the touch region TA. A first electrode pattern portion 156 and a second electrode pattern portion 166 that function as position detection electrodes may be arranged in the touch region TA of the touch panel 100′. The pad portion PP1 has electrodes arranged to receive or transmit signals from the outside of the touch panel 100′, and may include, for example, a first touch pad and a second touch pad. Hereinafter, descriptions of components that are identical to those described below will be omitted and differences will be described with reference to FIG. 1.

In an embodiment, the first electrode pattern portion 156 may have a plurality of arrangements disposed parallel in the first direction X. The first electrode pattern portion 156 includes first sensor electrodes 150 and 154 in a rhombus shape or a diamond shape, and bridges 152 connecting adjacent first sensor electrodes 150 and 154. Additionally, the first sensor electrodes 150 and 154 are electrically connected to the first signal wire 158 and receive a driving voltage through the first touch pad disposed on the pad portion PP1.

In an embodiment, the second electrode pattern portion 166 may be arranged in plural to be disposed parallel to the second direction Y so as to intersect the first electrode pattern portion 156. The second electrode pattern portion 166 may include second sensor electrodes 160 and 164 having a rhombus shape or a diamond shape, and a connection 162 connecting the second sensor electrodes 160 and 164 that are disposed in the same layer as the second sensor electrodes 160 and 164 and are disposed adjacent to each other in the second direction. These second sensor electrodes 160 and 164 are electrically connected to the second signal wire 168 and supply a voltage or a current, which changes depending on whether or not a touch is detected, to the second touch pad disposed at the pad portion PP1.

In an embodiment and referring to FIG. 1 and FIG. 2, as described above, the pad portion PP1 disposed in the peripheral area NA of the display panel 100 or the touch panel and the flexible printed circuit board 200 may be connected. That is, the flexible printed circuit board 200 may be connected together to electrodes for transmitting the driving signal of the display panel and electrodes for transmitting a detection signal of the touch panel. However, the invention is not limited to this, and in another embodiment, a flexible printed circuit board for driving the display panel and a flexible printed circuit board for detecting the touch panel may be provided separately, which is also within the scope of the invention. Hereinafter, the flexible printed circuit board 200 connected to the display panel 100 and the touch panel 100′ will be discussed, using the example of its configuration.

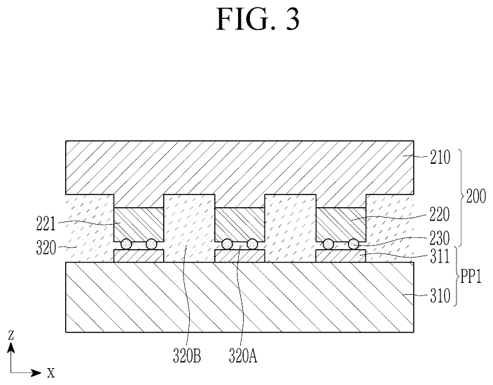

FIG. 3 is a cross-sectional view taken along a line III-III′ of FIG. 1, according to an embodiment. The structure in which the flexible printed circuit board 200, a nonconductive film 320, and the pad portion PP1 of the display panel 100 are bonded, according to an embodiment, is described with reference to FIG. 3.

In an embodiment and referring to FIG. 3, the pad portion PP1 of the flexible printed circuit board 200 and the display panel 100 may be bonded while facing each other with a nonconductive film (NCF) 320 interposed therebetween.

In an embodiment, the pad portion PP1 of the display panel 100 may include a substrate 310 and a plurality of pads 311. The substrate 310 may include an insulating material such as glass or plastic. The plurality of pads 311 may be disposed on the substrate 310. The substrate 310 extends in the first direction X and the second direction Y, and is directed perpendicular towards a third direction Z. The plurality of pads 311 may include a conductive material such as copper (Cu) and may be connection pads that electrically connect the display panel 100 and the flexible printed circuit board 200. For example, the width of each of the plurality of pads 311 may be approximately 10 μm.

In an embodiment, the nonconductive film 320 may include a thermosetting resin (e.g., epoxy resin, acryl resin, polyester resin, bismaleimide resin, cyanate resin, etc.). The flexible printed circuit board 200 and the display panel 100 may be mechanically bonded by the nonconductive film 320.

In an embodiment, the flexible printed circuit board 200 includes a base film 210, a wiring layer 220, and a plurality of conductive balls 230. The wiring layer 220 may be disposed on the base film 210, and the plurality of conductive balls 230 may be disposed on the wiring layer 220. The plurality of conductive balls 230 may be partially embedded in an upper surface of the wiring layer 220. The wiring layer 220 may include the plurality of wires 221, and the plurality of conductive balls 230 may be partially embedded in an upper surface of the plurality of wires 221. No conductive ball may be disposed between the plurality of wires 221.

In an embodiment and referring to FIG. 3, the nonconductive film 320 may be disposed between the flexible printed circuit board 200 and the pad portion PP1 of the display panel 100. The plurality of conductive balls 230 may be disposed between the plurality of wires 221 of the flexible printed circuit board 200 and the plurality of pads 311 of the pad portion PP1 of the display panel 100. The plurality of pads 311 and the plurality of conductive balls 230 disposed on the upper surface of the plurality of wires 221 aligned with the plurality of pads 311 may be in physical contact. That is, the plurality of pads 311 and the plurality of wires 221 aligned thereto may be electrically connected via the plurality of conductive balls 230. The plurality of conductive balls 230 may also be partially embedded in the plurality of pads 311, but the depth embedded in the plurality of pads 311 is smaller than the depth embedded in the wiring layer 220. The space between the plurality of adjacent pads 311 or between the plurality of adjacent wires 221 may be filled with the nonconductive film 320, with no conductive balls disposed therebetween. The nonconductive film 320 may also be disposed between the plurality of pads 311 and the plurality of wires 221.

In an embodiment, the nonconductive film 320 may include a first region 320A that overlaps the wiring layer 220 on a plane and a second region 320B that does not overlap the wiring layer 220. The first region 320A may be in contact with the plurality of conductive balls 230, and the second region 320B may not be in contact with the plurality of conductive balls 230.

In an embodiment, since the plurality of conductive balls 230 are embedded in the upper surface of the wiring layer 220, the flexible printed circuit board 200 may not require an additional conductive adhesive member, such as an anisotropic conductive film (ACF), when being bonded to the display panel 100.

Additionally, in an embodiment, since the plurality of conductive balls 230 are embedded in the wiring layer 220, it is easy to electrically connect the plurality of wires 221 and the plurality of pads 311. That is, even if the flexible printed circuit board 200 is connected to the display panel 100 by interposing a nonconductive film (NCF), electrical connection of the plurality of wires 221 and the plurality of pads 311 is possible. A narrowing of the width of each of the plurality of pads 311 or the plurality of wires 221 or a narrowing of the spacing between each of the plurality of pads 311 or the plurality of wires 221 does not result in a region where the conductive balls are not captured between the plurality of wires 221 and the plurality of pads 311. Therefore, the flexible printed circuit board 200, according to an embodiment, may ensure the connection reliability with the display panel 100.

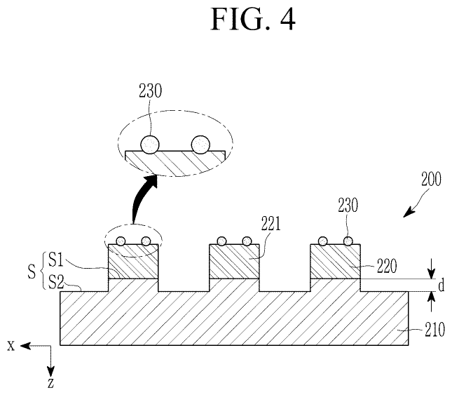

FIG. 4 is a cross-sectional view illustrating a flexible printed circuit board 200 shown in FIG. 3, according to an embodiment.

In an embodiment and referring to FIG. 4, the flexible printed circuit board 200 includes a base film 210, a wiring layer 220, and a plurality of conductive balls 230.

In an embodiment, the base film 210 is a part that becomes the body of the flexible printed circuit board 200 and may be made of a material such as polyimide. The thickness of the base film 210 may be, for example, approximately 20 μm, but is not limited thereto, and may be determined within a range that allows the flexible printed circuit board 200 to be flexible and rigid at the same time while not deforming.

In an embodiment, the wiring layer 220 may be disposed on the base film 210. The wiring layer 220 may include the plurality of wires 221. The wiring layer 220 may be made of a material such as copper (Cu). The thickness of the wiring layer 220 in the third direction Z may be, for example, approximately 8 μm to approximately 20 μm. The width of each of the plurality of wires 221 in the wiring layer 220 may be, for example, approximately 10 μm.

In an embodiment, the plurality of conductive balls 230 may be disposed above the wiring layer 220. The plurality of conductive balls 230 may be embedded in the upper surface of the wiring layer 220. The plurality of conductive balls 230 may be partially embedded in the upper surface of the wiring layer 220, and, for example, the plurality of conductive balls 230 may be embedded in a manner that protrudes from the upper surface of the wiring layer 220.

In an embodiment, a hardness of the plurality of conductive balls 230 may be higher than a hardness of the wiring layer 220. The plurality of conductive balls 230 may be made of conductive materials such as nickel (Ni), molybdenum (Mo), chromium (Cr), tantalum (Ta), and titanium (Ti). Without being limited thereto, the plurality of conductive balls 230 may be in the form of a nonconductive material such as a polymer, coated with a conductive material such as nickel (Ni), gold (Au), or the like. The diameter of the plurality of conductive balls 230 may be, for example, approximately 1 μm to approximately 5 μm.

In an embodiment and referring to FIG. 4, on the upper surface S of the base film 210, a portion S1 in contact with the wiring layer 220 may have a higher step than a portion S2 not in contact with the wiring layer 220. Since the diameter of the conductive ball is smaller than the thickness of the wiring layer 220, the thickness d of the step may be smaller than the thickness of the wiring layer 220 when measured in the vertical direction (e.g., z direction) to the upper surface S of the base film 210.

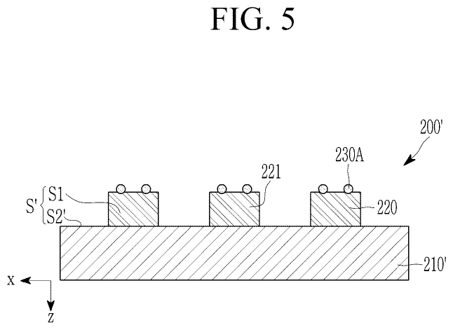

FIG. 5 is a cross-sectional view of a flexible printed circuit board 200′, according to another embodiment.

In an embodiment and referring to FIG. 5, the upper surface S′ of the base film 210′ in the flexible printed circuit board 200′ may be a flat surface without a step. That is, the portion S2′ that is not contact with the wiring layer 220 and the portion S1 that is in contact with the wiring layer 220 may be disposed on the same plane.

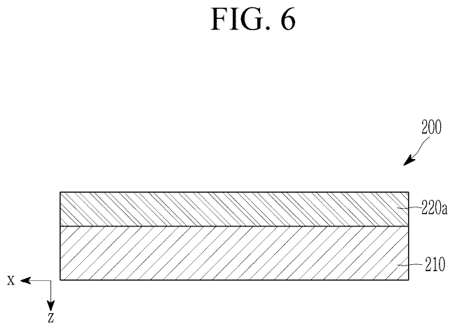

FIG. 6 to FIG. 10 are cross-sectional views sequentially showing a manufacturing method of a flexible printed circuit board 200, according to an embodiment.

In an embodiment and referring to FIG. 6 to FIG. 10, the manufacturing method of the flexible printed circuit board 200 may include forming a wire formation layer 220a on a base film 210, forming a wiring layer 220 by patterning the wire formation layer 220a, partially embedding at least some of a plurality of conductive balls 230 on the upper surface of the wiring layer 220, and removing the remaining conductive balls 230B that are not embedded in the wiring layer 220.

In an embodiment and referring to FIG. 6, the wire formation layer 220a may be formed on the base film 210. The base film 210 is a body part of the flexible printed circuit board 200 and may be made of a material such as polyimide. The thickness of the base film 210 may be, for example, approximately 20 μm. The wire formation layer 220a may be made of a material such as copper (Cu). The thickness of the wire formation layer 220a may be, for example, approximately 8 μm to approximately 20 μm.

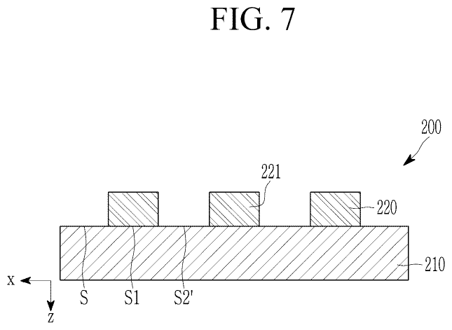

In an embodiment and referring to FIG. 7, the wiring layer 220 may be formed by patterning the wire formation layer 220a of FIG. 6 on the base film 210. For example, a photoresist pattern may be formed as an etching mask on the upper surface of the wire formation layer 220a of FIG. 6, followed by exposure and development, and then an etchant may be applied to remove a portion that will not become the wiring layer 220.

In an embodiment, the wiring layer 220 may include the plurality of wires 221. The width of each of the plurality of wires 221 in the wiring layer 220 may be, for example, approximately 10 μm. The upper surface S of the base film 210 may include a portion S1 that is in contact with the wiring layer 220 and a portion S2′ that is not in contact with the wiring layer 220.

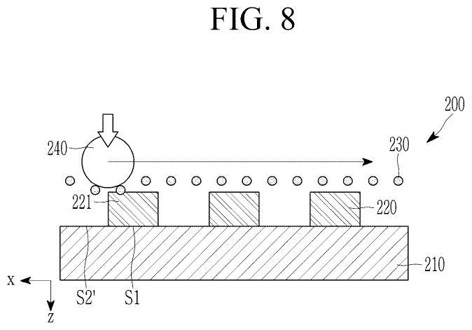

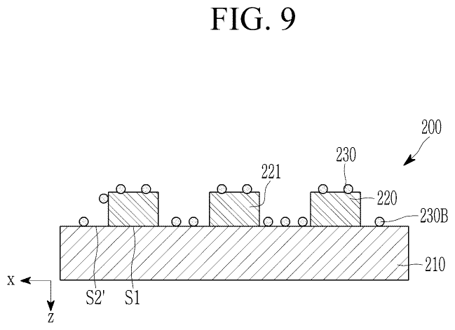

In an embodiment and referring to FIG. 8 and FIG. 9, the plurality of conductive balls 230 may be disposed and pressed onto the base film 210 on which the wiring layer 220 is formed. The plurality of conductive balls 230 may have a higher hardness than the wiring layer 220. For example, the plurality of conductive balls 230 may be pressed into the wiring layer 220 using a roller 240. The roller 240 may be in the form of a cylinder, and the diameter of the cylindrical roller 240 may be larger than the distance between the plurality of wires 221. Pressure may be applied by rolling the cylinder-shaped roller 240 on the plurality of conductive balls 230 disposed on the wiring layer 220. Accordingly, at least some of the plurality of conductive balls 230 may be embedded in the upper surface of the wiring layer 220. The plurality of conductive balls 230 may be partially embedded in the upper surface of the wiring layer 220, for example, such as protruding from the upper surface of the wiring layer 220.

In an embodiment and referring to FIG. 9, the remaining conductive balls 230B, which are not embedded among the plurality of conductive balls 230, may be disposed on the portion S2′ of the upper surface S of the base film 210 that does not come into contact with the wiring layer. That is, the remaining conductive balls 230B may be disposed between the plurality of wires 221.

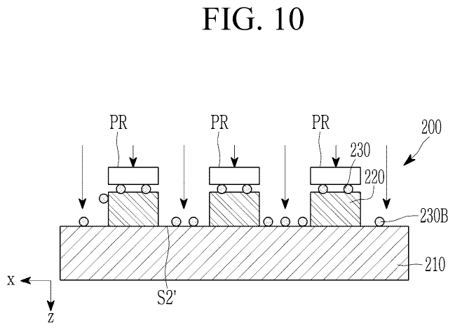

In an embodiment and referring to FIG. 10, the remaining conductive balls 230B disposed on the portion S2′ that is not in contact with the wiring layer 220 may be removed through an etching process. For example, by using a wet etching method, a photoresist pattern PR may be formed as an etching mask on the upper surface of the wiring layer 220, followed by exposure and development, and then an etchant may be applied to remove the remaining conductive balls 230B. Without limitation, in another embodiment, the remaining conductive balls 230B may be removed by dry etching using plasma, etc. In the process of removing the remaining conductive balls 230B, a portion of the base film 210 may also be etched together—for example, it may be etched to the extent of the diameter of the remaining conductive balls 230B. Accordingly, as shown in FIG. 4, on the upper surface S of the base film 210, the portion S1 in contact with the wiring layer 220 may have a higher step than the portion S2 not in contact with the wiring layer. Since the diameter of the remaining conductive balls 230B is smaller than the thickness of the wiring layer 220, the thickness d of the step may be smaller than the thickness of the wiring layer 220 in the thickness measured in the direction perpendicular to the upper surface S of the base film 210.

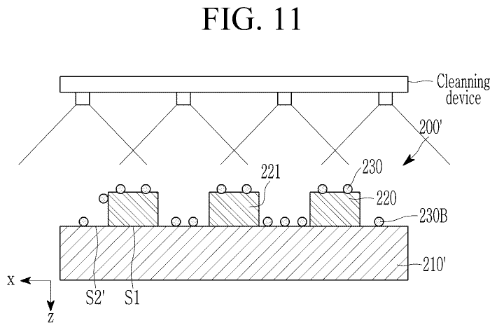

FIG. 11 is a cross-sectional view showing a manufacturing method of a flexible printed circuit board 200′, according to another embodiment.

In an embodiment and referring to FIG. 11, in the manufacturing method of the flexible printed circuit board 200′, the remaining conductive balls 230B may be removed through a cleaning process. The remaining conductive balls 230B are not embedded in the base film 210′ or the wiring layer 220, so they may be removed during, for example, the physical cleaning step. Accordingly, as shown in FIG. 5, the upper surface S′ of the base film 210′ may be a flat surface without steps. That is, the portion S2′ that is not in contact with the wiring layer 220 and the portion S1 that is in contact with the wiring layer 220 may be disposed on the same plane.

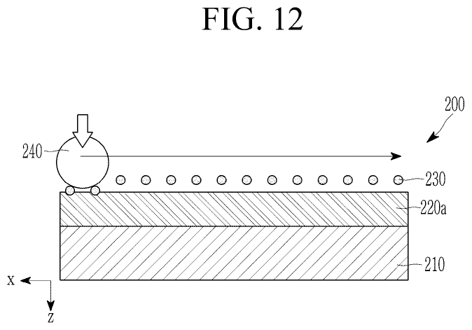

FIG. 12 to FIG. 14 are cross-sectional views showing a manufacturing method of a flexible printed circuit board 200, according to another embodiment.

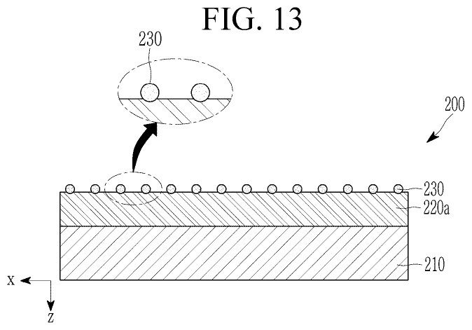

Hereinafter, referring to FIG. 12 to FIG. 13, together with FIGS. 4 and 5, a method of manufacturing a flexible printed circuit board 200, according to another embodiment will be described.

In an embodiment and referring to FIG. 12 to FIG. 14, the method for manufacturing the flexible printed circuit board 200 may include forming a wire formation layer 220a on a base film 210, partially embedding a plurality of conductive balls 230 in the upper surface of the wire formation layer 220a, patterning the wire formation layer 220a to form a wiring layer 220, and removing at least a portion of the plurality of conductive balls 230.

First, in an embodiment and referring to FIG. 12 and FIG. 13, the wire formation layer 220a may be formed on the base film 210. The plurality of conductive balls 230 may be disposed and pressed onto the wire formation layer 220a. The plurality of conductive balls 230 may have a higher hardness than the wire formation layer 220a. For example, the plurality of conductive balls 230 may be pressed into the wire formation layer 220a by using a roller 240. The roller 240 may be in the form of a cylinder, and in this case, there is no limitation on the diameter size of the cylinder-shaped roller 240. Pressure may be applied by rolling the cylinder-shaped roller 240 on the plurality of conductive balls 230 disposed on the wire formation layer 220a. At least some of the plurality of conductive balls 230 may be partially embedded in the upper surface of the wire formation layer 220a. The plurality of conductive balls 230 may be embedded in a form that protrudes above the upper surface of the wire formation layer 220a.

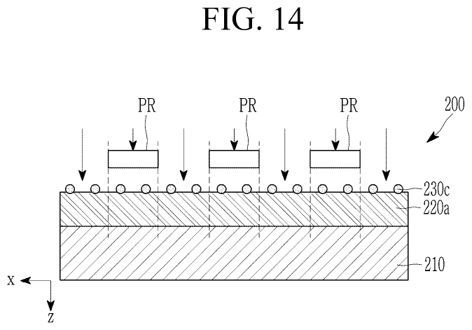

In an embodiment and referring to FIG. 14, the wiring layer 220 may be formed by patterning the wire formation layer 220a. The wiring layer 220 may include the plurality of wires 221. When patterning the wire formation layer 220a, the conductive balls 230C disposed over the region to be removed in the wire formation layer 220a may be simultaneously removed. Without limitation, the conductive balls 230C disposed over the region to be removed may be removed through a separate etching process. In the process of removing the conductive balls 230C disposed over the region to be removed, a portion of the base film 210 may also be etched. Depending on the etching degree of the base film 210, the flexible printed circuit board having the structure as shown in FIG. 4 or FIG. 5 may be manufactured.

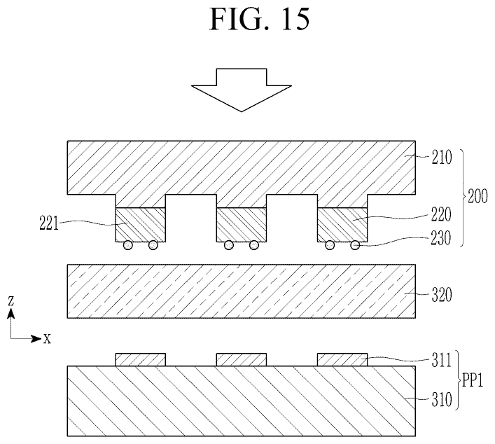

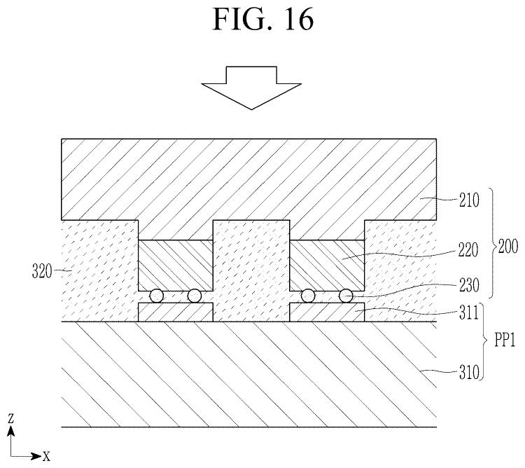

FIG. 15 and FIG. 16 are cross-sectional views illustrating a process of bonding a flexible printed circuit board 200, a nonconductive film 320, and a pad portion PP1 of a display panel 100, according to an embodiment. Hereinafter, together with FIG. 3 described above, with reference to FIG. 15 and FIG. 16, the structure and the bonding process of the flexible printed circuit board 200 and the pad portion PP1 of the display panel 100, according to an embodiment, will be described.

In an embodiment and referring to FIG. 15 and FIG. 16, the plurality of wires 221 of the flexible printed circuit board 200 and the plurality of pads 311 of the pad portion PP1 of the display panel 100 may be bonded to face each other with a nonconductive film 320 disposed therebetween.

According to an embodiment, the flexible printed circuit board 200 and the pad portion PP1 of the display panel 100 may be bonded through an outer lead bonding (OLB) process with the nonconductive film 320 interposed therebetween. The OLB process involves thermo-compressing the flexible printed circuit board 200, which may be performed using a heating tool called a hot bar. When the flexible printed circuit board 200 is thermo-compressed, heat and pressure are applied to the nonconductive film 320, and the nonconductive film 320 to which heat and pressure are applied becomes fluidic. At this time, the plurality of pads 311 and the plurality of conductive balls 230 disposed on the upper surface of the plurality of wires 221 aligned thereto may be in physical contact. Accordingly, the plurality of pads 311 and the plurality of wires 221 aligned thereto may be electrically connected via the plurality of conductive balls 230. During this process, the nonconductive film 320 may be cured, and the flexible printed circuit board 200 may be mechanically bonded to the display panel 100. In the process of thermo-compressing the flexible printed circuit board 200, the plurality of conductive balls 230 may also be embedded in the plurality of pads 311, but the depth at which the plurality of pads 311 are embedded is smaller than the depth at which the wiring layer 220 is embedded.

In an embodiment, the nonconductive film 320 may include the first region 320A that is aligned to the wiring layer 220 on a plane and the second region 320B that does not overlap the wiring layer 220. The first region 320A may be in contact with the plurality of conductive balls 230, and the second region 320B may not be in contact with the plurality of conductive balls 230. That is, no conductive ball may be disposed between the plurality of wires 221. Additionally, no conductive ball may be disposed between the plurality of pads 311.

According to an embodiment, the flexible printed circuit board 200 may not require an additional conductive adhesive member, such as an anisotropic conductive film (ACF), during the OLB process because the plurality of conductive balls 230 are already embedded in the upper surface of the wiring layer 220 before performing the OLB process. Additionally, since the plurality of conductive balls 230 are embedded in the wiring layer 220, it is easy to electrically connect the plurality of wires 221 and the plurality of pads 311. Even if the width of the plurality of pads 311 or the plurality of wires 221 is narrowed, there is no region where the conductive balls are not captured between the plurality of wires 221 and the plurality of pads 311. Therefore, the flexible printed circuit board 200, according to an embodiment, may have a reliable electrical connection with the display panel 100.

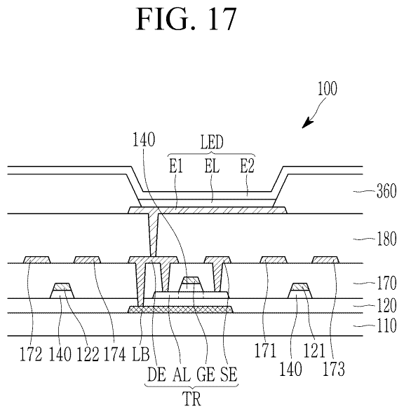

FIG. 17 is a cross-sectional view of a display area in a display device, according to an embodiment. Hereinafter, an exemplary structure of the display panel 100 to which the flexible printed circuit board 200 is bonded is described with reference to FIG. 17.

In an embodiment and referring to FIG. 17, the display panel 100 of the display device includes a substrate 110 and various layers, elements, and wires formed thereon. The substrate 110 may include an insulating material such as glass or plastic.

In an embodiment, a light blocking layer LB may be disposed on the substrate 110. The light blocking layer LB blocks external light from reaching the semiconductor layer AL of the transistor TR, thereby preventing degradation of the semiconductor layer AL. The light blocking layer LB may function as an electrode that receives a specific voltage from the display panel 100. In this case, a current variation ratio may decrease in a saturation region of a voltage-current characteristic graph of the transistor TR. The light blocking layer LB may include copper (Cu), aluminum (Al), silver (Ag), chromium (Cr), titanium (Ti), tantalum (Ta), etc., and may be a single layer or multiple layers.

In an embodiment, between the substrate 110 and the light blocking layer LB, a barrier layer that includes an inorganic insulating material such as silicon nitride (SiNx), silicon oxide (SiOx), or silicon oxynitride (SiOxNy) may be further disposed. The barrier layer may be a single layer or multiple layers.

In an embodiment, a buffer layer 120 may be disposed above the light blocking layer LB. The buffer layer 120 blocks impurities that may diffuse from the substrate 110 to the semiconductor layer AL during the process of forming the semiconductor layer AL, and can reduce stress applied to the substrate 110. The buffer layer 120 may include an inorganic insulating material such as silicon nitride (SiNx), silicon oxide (SiOx), or silicon oxynitride (SiOxNy), and may be a single layer or multiple layers.

In an embodiment, the semiconductor layer AL may be disposed on the buffer layer 120. The semiconductor layer AL may include a channel region of the transistor TR, and a source region and a drain region on either side thereof. The semiconductor layer AL may include any one of amorphous silicon, polycrystalline silicon, and an oxide semiconductor. For example, the semiconductor layer AL may include a low-temperature polysilicon (LTPS) or an oxide semiconductor material containing at least one of zinc (Zn), indium (In), gallium (Ga), and tin (Sn). For example, the semiconductor layer may include IGZO (indium-gallium-zinc oxide).

In an embodiment, a gate insulating layer 140 may be disposed on the semiconductor layer AL. The gate insulating layer 140 may include an inorganic insulating material such as silicon nitride (SiNx), silicon oxide (SiOx), and silicon oxynitride (SiOxNy), and may be a single layer or multiple layers.

In an embodiment, a gate conductive layer that may include a gate electrode GE of the transistor TR, a first scan line 121, a second scan line 122, etc. may be disposed on the gate insulating layer 140. The gate conductive layer may include molybdenum (Mo), aluminum (Al), copper (Cu), titanium (Ti), and the like, and may be a single layer or multiple layers.

In an embodiment, an interlayer insulating layer 170 may be disposed on the gate conductive layer. The interlayer insulating layer 170 may include an inorganic insulating material such as silicon nitride (SiNx), silicon oxide (SiOx), and silicon oxynitride (SiOxNy), and may be a single layer or multiple layers.

In an embodiment, a data conductive film, which may include a first electrode SE and a second electrode DE of the transistor TR, a data line 171, a driving voltage line 172, a common voltage line 173, an initialization voltage line 174, etc., may be disposed on the interlayer insulating layer 170. The second electrode DE may be connected to the light blocking layer LB through a contact hole formed in the interlayer insulating layer 170 and the buffer layer 120. The data conductive film may include aluminum (Al), platinum (Pt), palladium (Pd), silver (Ag), magnesium (Mg), gold (Au), nickel (Ni), neodymium Nd, iridium (Ir), chromium (Cr), calcium (Ca), molybdenum (Mo), titanium (Ti), tungsten (W), copper (Cu), and the like, and may be a single layer or multiple layers.

In an embodiment, a planarization layer 180 may be disposed on the data conductive film. The planarization layer 180 may be an organic layer. For example, the planarization layer 180 may include an organic insulating material such as a general-purpose polymer such as poly(methyl methacrylate) or polystyrene, a polymer derivative having a phenolic group, an acryl-based polymer, an imide polymer, a polyimide, an acryl-based polymer, and a siloxane-based polymer.

In an embodiment, a passivation layer that may include inorganic insulating materials such as silicon nitride (SiNx), silicon oxide (SiOx), and silicon oxynitride (SiOxNy) may be further disposed between the data conductive film and the planarization layer 180.

In an embodiment, a pixel electrode E1 of the light emitting diode LED may be disposed on the planarization layer 180. The pixel electrode E1 may be connected to the second electrode DE through a contact hole formed in the planarization layer 180. The pixel electrode E1 may be formed of a reflective conductive material or a semi-transmissive conductive material, or may be formed of a transparent conductive material. The pixel electrode E1 may contain a transparent conductive material such as indium tin oxide (ITO) or indium zinc oxide (IZO). The pixel electrode E1 may include a metal or metal alloy such as lithium (Li), calcium (Ca), aluminum (Al), silver (Ag), magnesium (Mg), and gold (Au).

In an embodiment, a pixel definition layer 360 having an opening overlapping the pixel electrode E1 may be disposed on the planarization layer 180. The pixel definition layer 360 may include an organic insulating material such as an acryl-based polymer or an imide-based polymer.

In an embodiment, t light emitting layer EL may be disposed on top of the pixel electrode E1. The light emitting layer EL may include organic or inorganic materials that emit red, green, and blue light. The light emitting layer EL, which emits red, green, and blue light, may include low-molecular or high-molecular organic materials. According to an embodiment, the light emitting layer (EL) may include quantum dots. The quantum dots (hereinafter, referred to as semiconductor nanocrystals) may include a Group II-VI compound, a Group III-V compound, a Group IV-VI compound, a Group IV element or compound, a Group I-III-VI compound, a Group II-III-VI compound, a Group I-II-IV-VI compound, or combinations thereof. The quantum dots may not include cadmium. In addition to the light emitting layer EL, at least one of a hole injection layer (HIL), a hole transport layer (HTL), an electron transport layer (ETL), and an electron injection layer (EIL) may be disposed on the pixel electrode E1.

In an embodiment, a common electrode E2 may be disposed on the light emitting layer EL. The common electrode E2 may be disposed across multiple pixels. The common electrode E2 may be made light-transmissive by forming a thin layer of a metal or a metal alloy having a low work function such as calcium (Ca), barium (Ba), magnesium (Mg), aluminum (Al), silver (Ag), or the like. The common electrode E2 may include a transparent conductive oxide such as indium tin oxide (ITO) or indium zinc oxide (IZO).

In an embodiment, the pixel electrode E1, the light emitting layer EL, and the common electrode E2 of each pixel PX form a light emitting diode (LED) such as an organic light emitting diode. The pixel electrode E1 may be an anode of the light emitting diode, and the common electrode E2 may be a cathode of the light emitting diode.

In an embodiment, an encapsulation layer may be disposed on the common electrode E2. The encapsulation layer may be a glass substrate bonded to the substrate 110 by a sealant. The encapsulation layer may be a thin-film encapsulation layer in which one or more inorganic layers and one or more organic layers are stacked. A color conversion layer including semiconductor nanocrystals (e.g., quantum dots, phosphors, etc.) may be disposed on the encapsulation layer.

A display device, according to an embodiment, may be applied to various electronic devices. An electronic device, according to an embodiment, may include the display device, and may further include modules or devices having additional functions other than the display device.

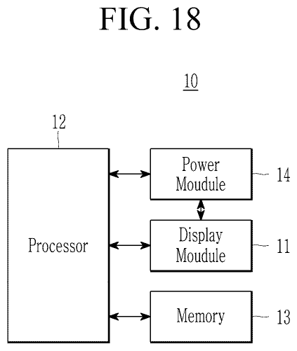

FIG. 18 is a block diagram of an electronic device, according to an embodiment. Referring to FIG. 18, the electronic device 10, according to an embodiment, may include a display module 11, a processor 12, a memory 13, and a power module 14.

In an embodiment, the processor 12 may include at least one of a central processing unit (CPU), an application processor (AP), a graphic processing unit (GPU), a communication processor (CP), an image signal processor (ISP), and a controller.

In an embodiment, the memory 13 may store data information necessary for operations of the processor 12 or the display module 11. When the processor 12 executes an application stored in the memory 13, video data signals and/or input control signals are transmitted to the display module 11, and the display module 11 can process the received signals to output video information through the display screen.

In an embodiment, the power module 14 may include a power supply module such as a power adapter or battery device, and a power conversion module that converts the power supplied by the power supply module to generate the power necessary for the operation of the electronic device 10.

In an embodiment, at least one of components of the electronic device 10 may be included within the display device. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 10 that are not part of the display device.

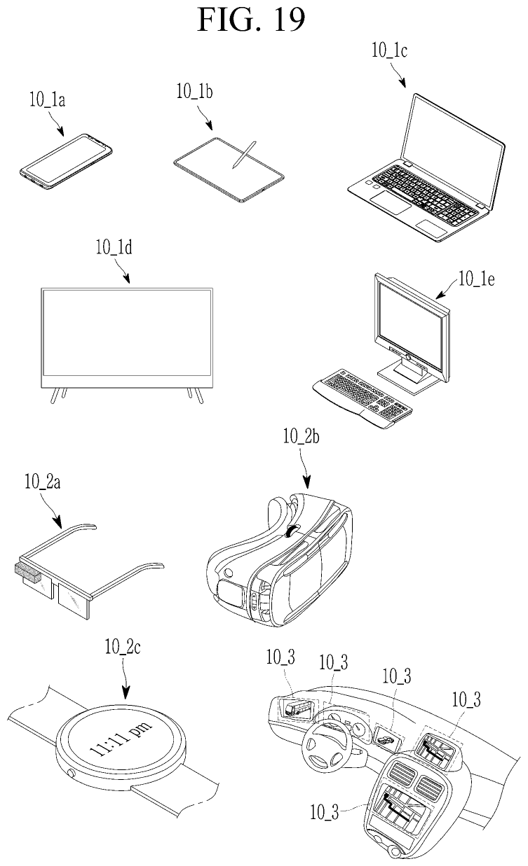

FIG. 19 shows graphical images of electronic devices, according to various embodiments.

Referring to FIG. 19, various electronic devices with the display device, according to various embodiments, may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

While the invention has been described in connection with what is presently considered to be practical embodiments, it is to be understood that the invention is not limited to the disclosed embodiments, but, on the contrary, is intended to cover various modifications and equivalent arrangements included within the spirit and scope of the invention. Therefore, the scope of the invention is not limited to the contents described in the detailed description of the specification. Moreover, the embodiments or parts of the embodiments may be combined in whole or in part without departing from the scope of the invention.

What is claimed is:

1. A display device comprising:
a display panel including a display area and a peripheral area;
a flexible printed circuit board facing and bonded to a pad portion disposed in the peripheral area; and
a nonconductive film disposed between the pad portion and the flexible printed circuit board,
wherein the flexible printed circuit board includes a plurality of conductive balls partially embedded into an upper surface of a wiring layer disposed on a base film, wherein
the pad portion has a portion that comes into contact with the plurality of conductive balls.

2. The display device of claim 1, wherein:
the wiring layer includes a plurality of wires, and
no conductive ball is disposed between the plurality of wires.

3. The display device of claim 1, wherein:
the pad portion includes a plurality of pads, and
no conductive ball is disposed between the plurality of pads.

4. The display device of claim 1, wherein:
the plurality of conductive balls protrudes from the upper surface of the wiring layer.

5. The display device of claim 1, wherein:
the plurality of conductive balls has a higher hardness than the wiring layer.

6. The display device of claim 5, wherein:
the wiring layer includes copper (Cu), and
the plurality of conductive balls includes at least one selected from a group consisting of nickel (Ni), molybdenum (Mo), chromium (Cr), tantalum (Ta), and titanium (Ti).

7. The display device of claim 5, wherein:
the plurality of conductive balls is in a form of polymer balls coated with a conductive material.

8. The display device of claim 1, wherein:
the wiring layer includes a plurality of wires,
the pad portion includes a plurality of pads,
a width of each of the plurality of wires and a width of each of the plurality of pads are larger than a diameter of each of the plurality of conductive balls.

9. The display device of claim 1, wherein:
a portion of an upper surface of the base film in contact with the wiring layer has a higher step than a portion of the upper surface of the base film not in contact with the wiring layer.

10. The display device of claim 9, wherein:
a thickness of the step measured in a direction perpendicular to the upper surface of the base film is smaller than a thickness of the wiring layer.

11. The display device of claim 1, further comprising:
an integrated circuit chip disposed on the base film in a region distinct from the wiring layer, wherein
the integrated circuit chip is electrically connected to the wiring layer.

12. A manufacturing method of a flexible printed circuit board comprising:
partially embedding a plurality of conductive balls into an upper surface of a wiring layer disposed on a base film; and
removing remaining conductive balls that are not embedded into the upper surface of the wiring layer.

13. The manufacturing method of the flexible printed circuit board of claim 12, wherein:
the plurality of conductive balls has a higher hardness than the wiring layer.

14. The manufacturing method of the flexible printed circuit board of claim 12, wherein:
partially embedding the plurality of conductive balls into the upper surface of the wiring layer includes positioning the plurality of conductive balls on the base film on which the wiring layer is formed, and
pressing at least some of the plurality of conductive balls into the upper surface of the wiring layer by using a roller.

15. The manufacturing method of the flexible printed circuit board of claim 12, wherein:
removing the remaining conductive balls includes etching the remaining conductive balls disposed in a portion of the upper surface of the base film that does not come into contact with the wiring layer among.

16. The manufacturing method of the flexible printed circuit board of claim 12, wherein:
removing the remaining conductive balls includes removing the remaining conductive balls through a cleaning process.

17. The manufacturing method of the flexible printed circuit board of claim 12, wherein:
partially embedding the plurality of conductive balls into the upper surface of the wiring layer includes,
forming a wire formation layer on the base film,
embedding the plurality of conductive balls into the upper surface of the wire formation layer, and
patterning the wire formation layer to form a wiring layer.

18. The manufacturing method of the flexible printed circuit board of claim 17, wherein:
forming the wiring layer includes patterning the wire formation layer in which the plurality of conductive balls are embedded to remove some of the plurality of conductive balls.

19. An electronic device comprising a display device, a memory, a processor, and a power supply module, the display device comprising:
a display panel including a display area and a peripheral area;
a flexible printed circuit board facing and bonded to a pad portion disposed in the peripheral area; and
a nonconductive film disposed between the pad portion and the flexible printed circuit board,
wherein the flexible printed circuit board includes a plurality of conductive balls partially embedded into an upper surface of a wiring layer disposed on a base film, and
the pad portion has a portion that comes into contact with the plurality of conductive balls.

20. The electronic device of claim 19, wherein:
the wiring layer includes a plurality of wires, and
no conductive ball is disposed between the plurality of wires.
